(19) United States
(12) Patent Application Publication
(10) Pub. No.: US 2006/0172685 A1
(43) Pub. Date: Aug. 3, 2006

(54) Internal environmental control system and uses thereof

(76) Inventor: Paul O'Brien, Veradale, WA (US)

Correspondence Address: Sandra P. Thompson;Buchalter Nemer, A Professional Corporation, Suite 800, 18400 Von Karman, Irvine, CA, 92612, US

(21) Appl. No.: 11/230,691

(22) Filed: Sep. 20, 2005

Related U.S. Application Data
(60) Provisional application No. 60/612,061, filed on Sep. 21, 2004.

(30) Foreign Application Priority Data
Aug. 26, 2004 (WO) PCT/US04/27759

(51) Int. Cl. H05K 5/00

(52) U.S. Cl. 454/184

(57) ABSTRACT

An internal environment control system for an outdoor enclosure system is described that includes: a) at least one air intake component coupled to the outdoor enclosure system, b) at least one air exhaust component coupled to the outdoor enclosure system, c) an environmental detection device, d) an environmental regulation device coupled to the environmental detection device, the at least one air intake component, the at least one air exhaust component or a combination thereof, wherein the regulation device activates at least one of the at least one air intake component or the at least one air exhaust component, and e) at least one porous membrane, hydrophobic filter or combination thereof. Methods of controlling the internal environment of a remote enclosure system are also described herein that include: providing an internal environment control system comprising at least one porous membrane, hydrophobic filter or combination thereof; providing ambient air; and directing the ambient air through the internal environment control system.

This application claims priority to U.S. Provisional Patent Application Ser. No. 60/612,061 filed on Sep. 21, 2004 and PCT Application Serial No. PCT/US2004/027759 filed on Aug. 26, 2004, which are incorporated herein by reference in their entirety. This application will become a Continuation-In-Part to the National Stage US filing of PCT Application Serial No. PCT/US2004/027759 when it is filed.

### FIELD OF THE INVENTION

The field of the subject matter herein is environmental control systems, specifically, internal environmental control systems, such as those utilized in outdoor component cabinets, remote enclosure systems and/or remote access cabinets.

### BACKGROUND

The telecommunications and data communications industries have grown exponentially in the last 5 to 8 years partly because both industries have been able to expand their customer base from customers that are close to the center of operations/transmissions to customers who are located a significant distance from the center of operations/transmissions. Also, many of the components utilized at the operations site or at a remote site are more complex and yet are smaller/more compact. Expansion of data transmissions to customers located at significant distances from the center of operations is facilitated by remote sites that are portable and smaller than the center of operations site. Both industries include those utilities and industries that provide one-way and two-way data transmission and transportation. The telecommunications industry also includes wireless communications, wire-based communications and combinations thereof. Wireless communications includes infrared, satellite, antennae, etc. Wire-based communications includes fiber optic cable, conventional cable, coax cable, shielded and unshielded twisted pair cable, etc.

Data and telecommunication sites and/or remote sites usually contain electrical and telecommunications wiring and components, such as batteries, antennae, circuit boards, keypads and other related components that in many cases can be fragile, relatively inaccessible and certainly sensitive to the elements, such as heat, water, fog and humidity, and other environmental conditions. Therefore, these data and telecommunication sites, including remote sites, should be enclosed or otherwise contained in a protective enclosure system.

The data and telecommunication sites, including remote sites, should be monitored to identify system failures, such as surge suppression modules, air conditioners and fans, power reciters, batteries and other alarmed user equipment. Additionally, the monitoring shall report site changes, such as cabinet intrusion, temperature, environmental and humidity changes. The data and telecommunication sites, including remote sites, should also be environmentally controlled, such as with air conditioning, heating, and humidity control, so that the electrical and telecommunications components do not break down, short out or otherwise degrade leading to poor performance of the components or products.

Remote enclosure systems also present other layers of complexity when reviewing the viability of a remote site. If the remote site is small or otherwise constrained, the remote enclosure must be sufficiently small and accessible. If the remote site is in an area where there are environmental challenges, such as severe heat, rain, snow or extreme cold—the remote enclosure system should be able to withstand the environmental challenges, while being easy to access and easy with which to work.

Additionally, outdoor cabinet applications and/or remote enclosure systems are typically provisioned with environmental control systems that provide either heat exchangers or air conditioners, which are commonly powered by AC. Many of these environmental components are available on indoor applications, but are not equipped to handle the extremes of temperature that can be found outdoors. Due to the sensitive nature of the equipment and electronics, extreme heat can cause a thermal shutdown around 125° F. Additionally, if battery temperatures can be regulated around 77° F., peak life and performance can be achieved. In order to optimize the performance of environmental control systems in outdoor enclosures it is necessary to isolate the inside of the enclosure by making it as air tight as possible. However, this air tight quality can work against the application goal of 2-8 hour battery backup run times when AC power is lost, and/or at the AC powered environmental systems are lost as well. The heat generating equipment operating in a sealed space with moderate to high outdoor temperatures will continue to raise the internal temperature until a thermal shutdown occurs. This shut down condition can occur between 10-30 minutes, substantially less than the initial backup goal of 2-8 hours.

Based on the drawbacks, disadvantages and cost issues of environmental control of a conventional enclosure system, it would be useful to develop and implement an environmental control system that a) controls the internal space of the enclosure system; b) provides multiple access points for facilitating equipment repair and installation; c) is aesthetically functional given the cable entry and routing structure; d) can maximize battery life and performance, as well as maximizing the long-term use of the internal components and related electronics; and e) can mitigate, reduce or eliminate any liquid and/or water intrusion, such as that from rain, snow or flooding.

### SUMMARY OF THE SUBJECT MATTER

An internal environment control system for an outdoor enclosure system is described that includes: a) at least one air intake component coupled to the outdoor enclosure system, b) at least one air exhaust component coupled to the outdoor enclosure system, c) an environmental detection device, d) an environmental regulation device coupled to the environmental detection device, the at least one air intake component, the at least one air exhaust component or a combination thereof, wherein the regulation device activates at least one of the at least one air intake component or the at least one air exhaust component, and e) at least one porous membrane, hydrophobic filter or combination thereof.

Methods of controlling the internal environment of a remote enclosure system are also described herein that include: providing an internal environment control system comprising at least one porous membrane, hydrophobic filter or combination thereof; providing ambient air; and directing the ambient air through the internal environment control system.

### BRIEF DESCRIPTION OF THE FIGURES

FIG. 1 shows a contemplated enclosure system.

FIG. 2 shows a contemplated enclosure system.

FIG. 3 shows an interior view of a contemplated enclosure system.

FIG. 4A shows a contemplated internal environment control system.

FIG. 4B shows a contemplated internal environment control system.

FIG. 5 shows a contemplated internal environment control system.

FIG. 6 shows a contemplated internal environment control system.

FIG. 7A shows a contemplated internal environment control system.

FIG. 7B shows a contemplated internal environment control system.

FIG. 7C shows a contemplated internal environment control system.

FIG. 8A shows a contemplated internal environment control system.

FIG. 8B shows a contemplated internal environment control system.

FIG. 8C shows a contemplated internal environment control system.

Table 1 shows specifications for a contemplated embodiment of a remote enclosure system.

### DETAILED DESCRIPTION

An internal environment control system has been developed that a) controls the internal space of the enclosure system; b) provides multiple access points for facilitating equipment repair and installation; c) is aesthetically functional given the cable entry and routing structure; d) can maximize battery life and performance, as well as maximizing the long-term use of the internal components and related electronics; and e) can mitigate, reduce or eliminate any liquid and/or water intrusion, such as that from rain, snow or flooding.

An internal environment control system for an outdoor enclosure system is includes: a) at least one air intake component coupled to the outdoor enclosure system, b) at least one air exhaust component coupled to the outdoor enclosure system, c) an environmental detection device, and d) an environmental regulation device coupled to the environmental detection device, the at least one air intake component, the at least one air exhaust component or a combination thereof, wherein the regulation device activates at least one of the at least one air intake component or the at least one air exhaust component. Another contemplated internal environment control device further comprises at least one porous membrane, hydrophobic filter or combination thereof that is designed to protect, reduce or eliminate the internal environment from liquid and/or water intrusion, such as that from rain, fog, snow or flooding.

Methods of controlling the internal environment of a remote enclosure system are also described herein that include: providing an internal environment control system having at least one porous membrane, hydrophobic filter or combination thereof; providing ambient air; and directing the ambient air through the internal environment control system in such a way as to control the internal temperature and environment of a remote enclosure system. In addition, methods are provided that include filtering, reducing or substantially blocking liquid and/or water from entering the internal environment or space.

The at least one air intake component is coupled to the outdoor enclosure system. As used herein, the term “coupled” means that the at least one air intake component may be bolted to a door, top or side panel of the enclosure system, may hang on or from a door, top or side panel of the enclosure system, may be molded into a door, top or side panel of the enclosure system or a combination of the coupling embodiments thereof.

The at least one air intake component comprises at least one venting component. The at least one venting component may comprise at least one flap, and in some embodiments, a plurality of flaps. At least some of the plurality of flaps may be opened by creating a pressure differential between the internal environment and the environment external to the enclosure system. At least some of the plurality of flaps may also be opened mechanically by the environmental regulation device. The at least one venting component may also comprise at least one labyrinth inlet component, such as a labyrinth filtered inlet, that may comprise a plurality of baffles. The at least one venting component may also comprise at least one blower or fan. It is contemplated that the at least one blower and/or fan are operated by DC power, solar power, wind power or a combination thereof. At least part of the at least one air intake component may also comprise a temperature regulation device, such as a heating element, a cooling element or a combination thereof. The at least one air intake component may also comprise a motor that is coupled to at least part of or at least one of the venting components.

The at least one air exhaust component comprises at least one venting component. The at least one venting component may comprise at least one flap, and in some embodiments, a plurality of flaps. At least some of the plurality of flaps may be opened by creating a pressure differential between the internal environment and the environment external to the enclosure system. At least some of the plurality of flaps may also be opened mechanically by the environmental regulation device. The at least one venting component may also comprise at least one labyrinth outlet component, such as a labyrinth filtered outlet, that may comprise a plurality of baffles. The at least one venting component may also comprise at least one blower or fan. It is contemplated that the at least one blower and/or fan are operated by DC power, solar power, wind power or a combination thereof. The at least one air exhaust component may also comprise a motor that is coupled to at least part of or at least one of the venting components.

The at least one water/liquid filter component may also be coupled to the outdoor enclosure system. The at least one water/liquid filter component comprises at least one porous membrane, hydrophobic filter or combination thereof or other similar type of filter or membrane that allows ambient air into the internal environment without also allowing liquid, salt fog and/or water droplets into the internal environment. For example, GORE-TEX® is a contemplated membrane system that keeps water and snow droplets outside, while allowing the porous membrane to “sweat”, thus allowing a small amount of water and/or liquid inside the internal environment. In this way, the porous membrane is also “breathable” from the side of the internal environment, as opposed to the external environment. The at least one porous membrane, hydrophobic filter or combination thereof may also be coupled with a fabric, such as those that comprise nylon or polyester.

As mentioned, this at least one porous membrane, hydrophobic filter or combination thereof may be coupled to the outdoor enclosure system. The at least one porous membrane, hydrophobic filter or combination thereof may be coupled with the inlet shroud, the inlet baffle and/or the inlet filter. In addition, the at least one porous membrane, hydrophobic filter or combination thereof may be coupled to the air exhaust component. In some embodiments, the at least one porous membrane, hydrophobic filter or combination thereof will be coupled to both inlet and exhaust components. In yet other embodiments, the at least one porous membrane, hydrophobic filter or combination thereof will have its/their own opening or port on the outdoor enclosure system that is designed solely to provide a housing for the at least one porous membrane, hydrophobic filter or combination thereof.

The internal environment control system also comprises an environmental detection device that detects the environment inside the enclosure system. The environmental detection device can sense a loss of AC power in the outdoor enclosure system, a change of pressure in the outdoor enclosure system, a change of temperature in the outdoor enclosure system or a combination thereof.

The internal environment control system also comprises an environmental regulation device coupled to the environmental detection device, the at least one air intake component, the at least one air exhaust component or a combination thereof, wherein the regulation device activates at least one of the at least one air intake component or the at least one air exhaust component. The environmental regulation device is designed to activate at least one of the blowers in the at least one air intake component or the at least one air exhaust component, to open at least some of the plurality of flaps in the at least one air intake component or the at least one air exhaust component, to create a pressure differential in the internal environment or a combination thereof. It is contemplated that the environmental regulation device is operated by DC power, solar power, wind power or a combination thereof. The environmental regulation device may also activate the at least one motor coupled to the venting component of the at least one air intake component, the at least one motor coupled to the venting component of the at least one air exhaust component or a combination thereof.

In one contemplated embodiment, as mentioned earlier, an internal environmental control system may be utilized with any suitable enclosure system (such as a remote enclosure system, another electronic cabinet or electronic component system arrangement). Contemplated remote enclosure systems are disclosed in commonly-owned PCT Application Serial No.: PCT/US02/34800 filed on Oct. 30, 2002 and U.S. application Ser. No. 10/481,306 (filed on Dec. 17, 2003) and Ser. No. 10/793,619 (filed on Mar. 4, 2004, which is a continuation in part of Ser. No. 10/481,306), all of which claim priority to U.S. Provisional Application Ser. No. 60/379,480 filed on May 10, 2002 and which are all incorporated herein by reference in their entirety. But, it should be understood that the contemplated internal environmental control system may be utilized in a number of enclosure system arrangements, including those that are designed to be completely outdoors, completely indoors, or a combination of both outdoors and indoors.

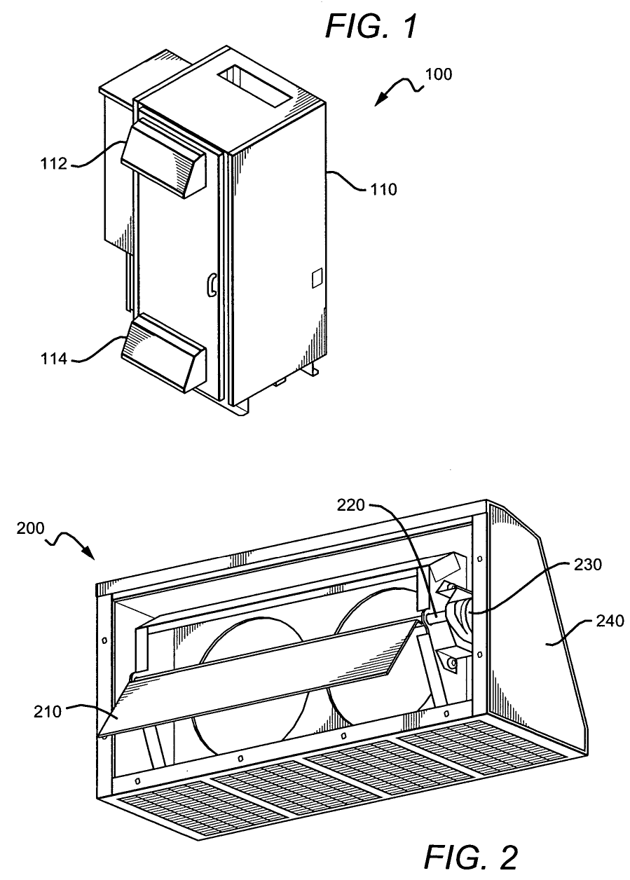

A contemplated internal environmental control system eliminates the previously-mentioned thermal shutdown condition while allowing for maximum battery runtimes on the available DC backup power—all without greatly impacting the run times by inducing more DC load. FIG. 1 shows a view of a contemplated enclosure system 100, which is in this case a remote enclosure system 110, with an internal environmental control system 120 that comprises both a auxiliary motor controlled fan driven exhaust 112 and a intake vent 114. The remote enclosure system 110 is similar to the ones shown and described in the above-referenced filed applications, which have already been incorporated herein by reference in their entirety. It should be understood that the internal environmental control system maintains the air tight nature of the enclosure during normal power conditions and opens a vent during a battery backup condition. Additionally, by thermostatically controlling the auxiliary cooling system, two other performance issues can be addressed: a) prevention of automatic operation in cold outdoor temperatures, and b) activation in a normal power mode in the event of a main environmental system failure. Other contemplated internal environmental control systems may comprise at least one of any or all of the following: an exhaust apparatus, an intake vent, an auxiliary cooling device or apparatus, auxiliary fans, auxiliary heating devices (for sub-freezing conditions), protective covering or shields, warning lights and/or devices, ducts or airflow direction piping, porous membranes designed for water/liquid control in and out of the internal environment, etc.

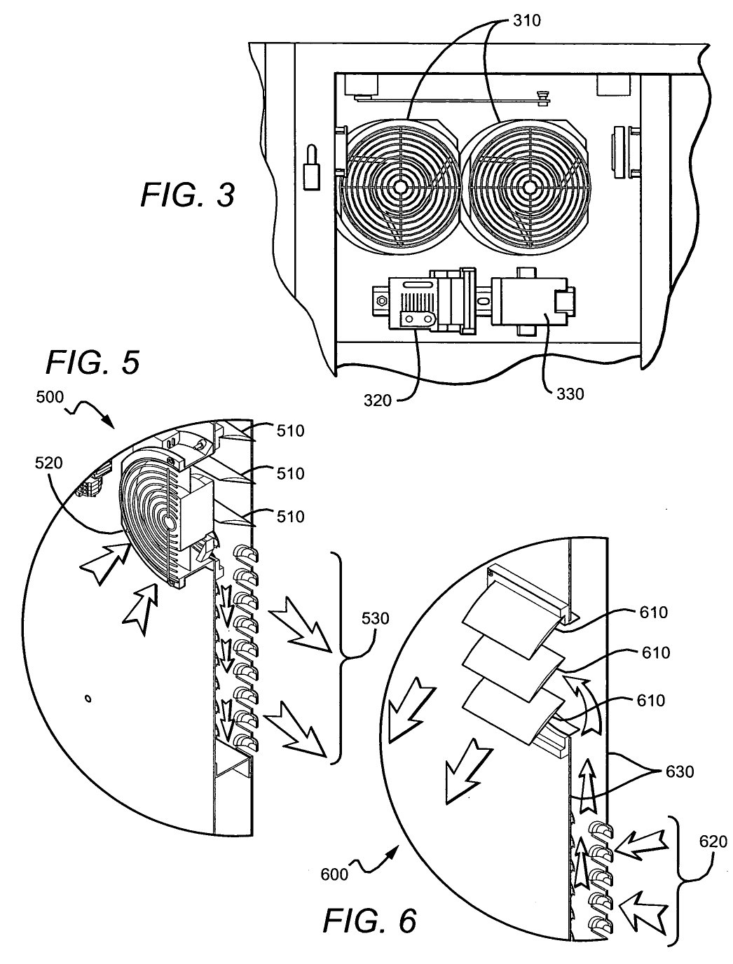

FIG. 2 shows another contemplated vent assembly 200 which comprises a motor-controlled spring returned flap 210 which is attached to a axle or rod 220 on a 24V AC-powered motor 230. A contemplated vent assembly also comprises at least one fan port 250 that matches or lines up with the door mounted fans (not shown). The components of the vent assembly 200 in this embodiment are at least partially enclosed by a NEMA 3R vent enclosure 240. The flap 210 is normally closed by a high tension spring and the flap seats on a gasket 260 attached to the vent surface. FIG. 3 shows the interior view of the door in FIG. 1 illustrating two DC-powered fans 310. FIG. 3 also shows a din rail mounted thermostat 320 and a 48V DC to 24V AC converter 330. The system operates when the thermostat reaches the adjusted thermal temperature, thereby powering the fans and powering the vent motors which open both the air intake and the exhaust. It is contemplated that the system will continue to operate until the temperature returns below the activation temperature. When this occurs, the system powers down stopping the fans and the springs close the flaps resealing the vents. These fan assemblies can be daisy-chained to address variable cooling requirements as the application dictates.

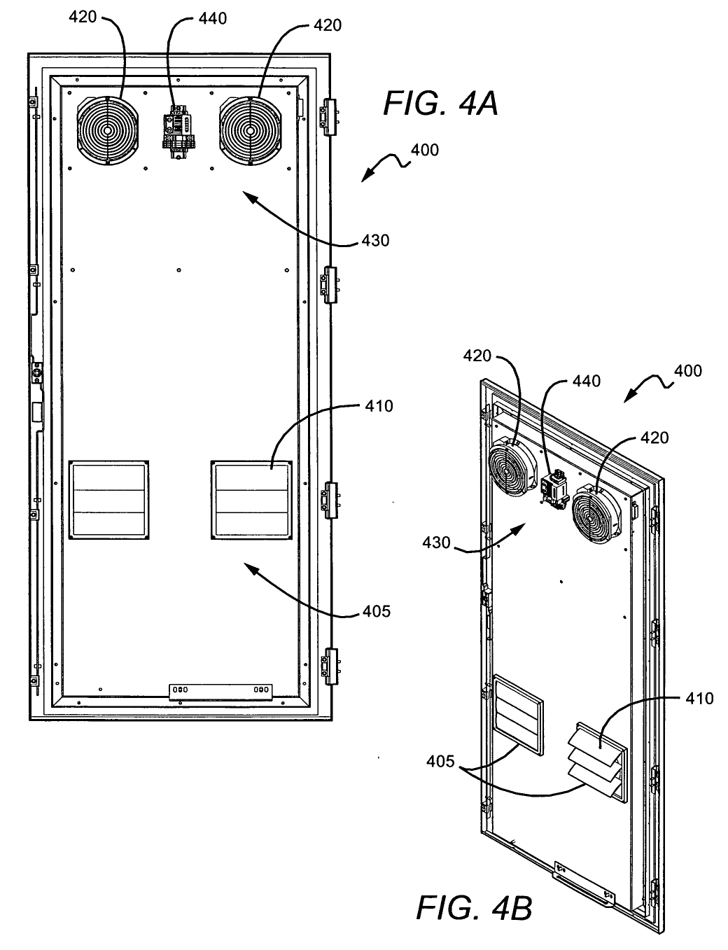

FIG. 4A and FIG. 4B shows a contemplated embodiment of the internal environment control system 400 for a remote enclosure system (not shown in its entirety). The air intake component 405 comprises a plurality of flaps 410 that are closed during normal operation of the components in the remote enclosure system. When the temperature conditions of the internal environment control system exceed a preset thermostat setting, the air exhaust component 430 is activated and a plurality of fans and/or blowers 420 that make up at least part of the air exhaust component 430 are activated by the environmental regulation device 440, which is a DC power source in this embodiment. A thermostat (not shown) acts as an environmental detection device in this embodiment. High temperature conditions, as discussed herein, are typically caused by air conditioner failure or AC power failure. When DC power is applied, the fans exhaust air from the system through at least part of the plurality of flaps in the air exhaust component, which open as a result of fan pressure, and the external baffles via a labyrinth. As air is drawn out of the remote enclosure system, fresh air is drawn into the enclosure system via at least some of the plurality of flaps of the air intake component. At least some of the plurality of flaps of the air intake component open under the force of the pressure differential between the internal environment and the outside environment (ambient). Both the air intake component and the air exhaust component are designed to prevent external influence, such as wind, that may cause them to open while the system in under normal operation. FIG. 5 shows a close-up view of an embodiment of the air exhaust component 500 that comprises a plurality of flaps 510, a fan/blower 520 and a labyrinth of baffles 530. FIG. 6 shows a close-up view of an embodiment of the air intake component 600 that comprises a plurality of flaps 610 and a labyrinth of baffles 620. In this embodiment of the internal environment control system, the space for the system is contained within the double wall door 630.

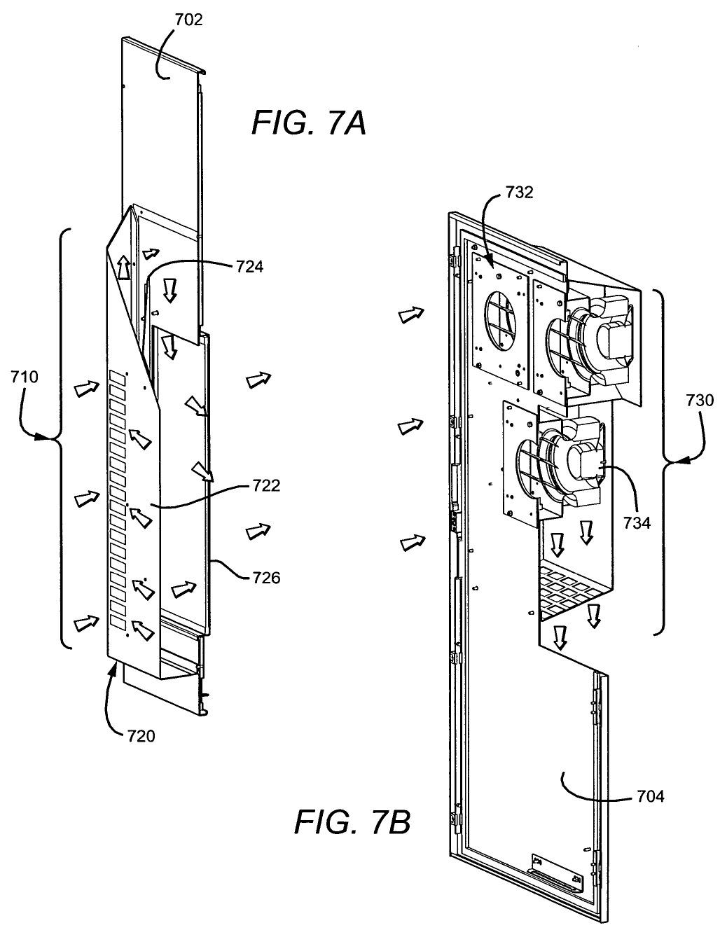

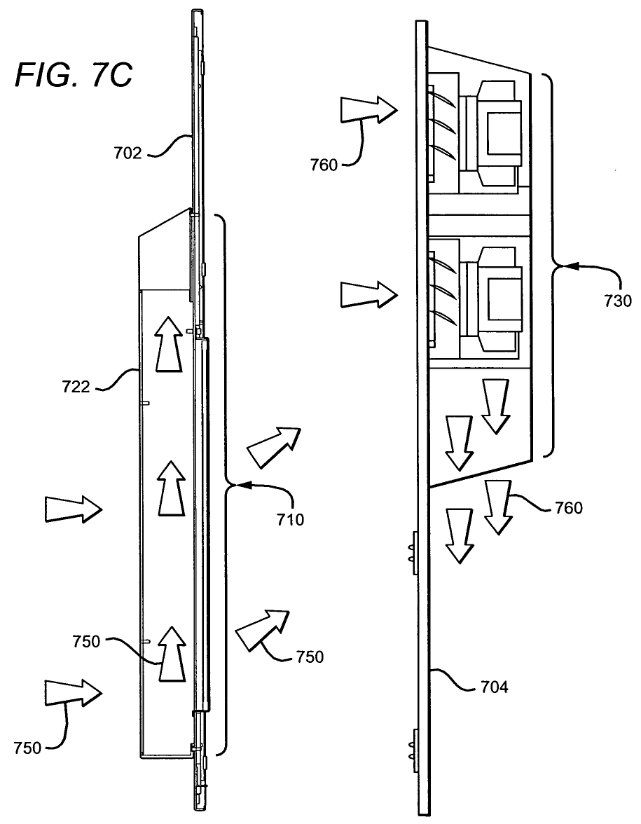

FIGS. 7A-7C show another contemplated embodiment of the internal environment control system where the system is coupled to at least two sides 702, 704 of an outdoor enclosure system, such as a remote enclosure system (not shown in its entirety). If there are additional cabinets coupled to the outdoor enclosure system, at least part of the internal environment control system may be coupled to one of the walls or doors of the additional cabinet, or there may be multiple internal environment control systems. As with the other embodiments described herein, the venting component may comprise a plurality of flaps on one or both of the air intake component or the air exhaust component in order to prevent recirculation of air. In this embodiment, the internal environment control system is designed for systems with high static pressure loads. The air intake component 710 may comprise a plurality of blowers (not shown), such as reverse curved impellers, that draw cooling air through a labyrinth filtered inlet 720 that comprises an inlet shroud 722, an inlet baffle 724 and an inlet filter 726, and exhaust the air through the air exhaust component 730 located in the rear door 704 of the outdoor enclosure system, wherein the air exhaust component 730 comprises an exhaust door assembly 732 and an exhaust fan blower assembly 734. Each of the blowers in the air intake component comprises a “check valve” type of flap system, such that if one of the plurality of blowers fails, the flaps on the failing blower will automatically close and prevent air from the other blowers recirculating back through the failed blower fan. Also, in this embodiment, each blower and related plurality of flaps is in a self-contained replaceable module to allow easy replacement, if needed. FIG. 7C shows the airflow into 750 the air intake component 710 and out of 760 the air exhaust component 730 in this contemplated embodiment.

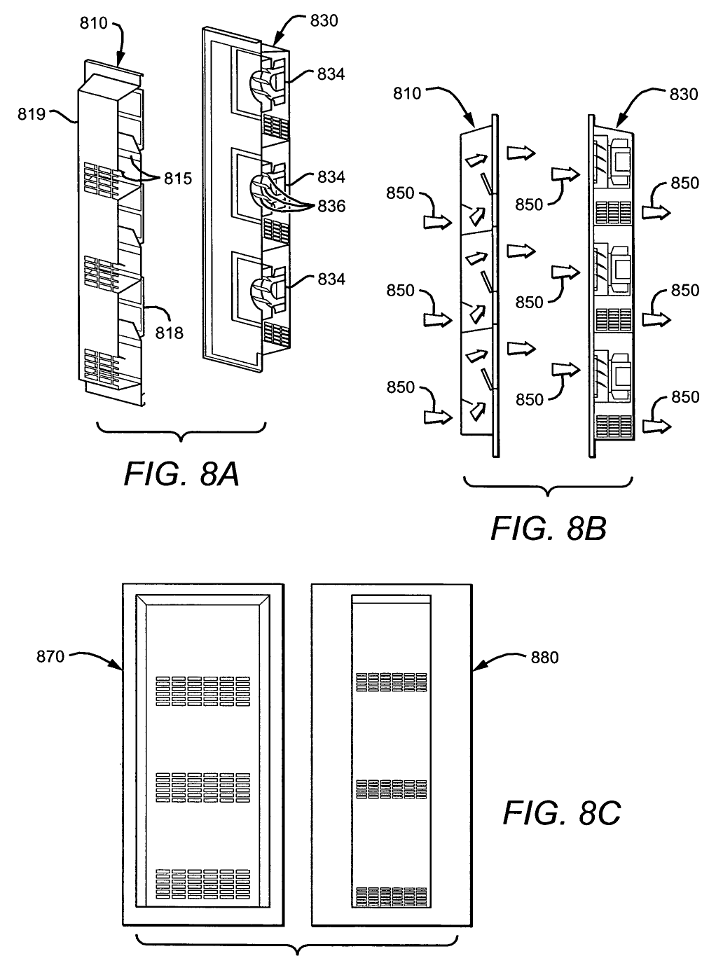

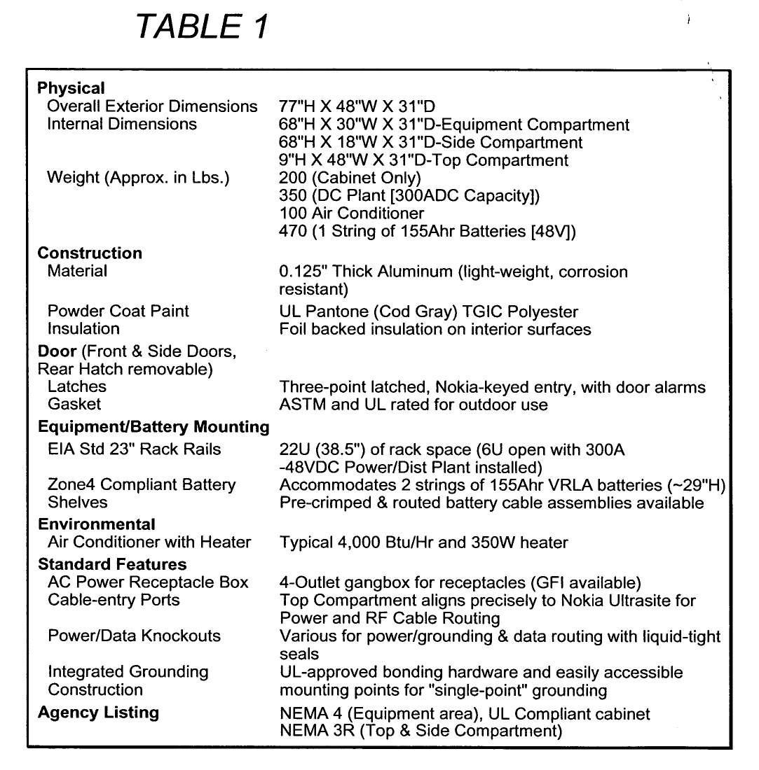

FIGS. 8A-8C show yet another contemplated embodiment of the internal environment control system where the system is coupled to at least two sides of an outdoor enclosure system, such as a remote enclosure system (not shown). If there are additional cabinets coupled to the outdoor enclosure system, at least part of the internal environment control system may be coupled to one of the walls or doors of the additional cabinet, or there may be multiple internal environment control systems. As with the other embodiments described herein, the venting component may comprise a plurality of flaps or a flap system on one or both of the air intake component or the air exhaust component in order to prevent recirculation of air. The air intake component or intake door assembly 810 may comprise inlet baffles 815, an intake filter 818 and an inlet shroud 819. The inlet baffles 815 and intake filter 818 work to direct and filter air coming into the internal environment. A plurality of blowers (not shown), such as reverse curved impellers, may also be used to draw cooling air through intake door assembly 810 that comprises an inlet shroud 819, an inlet baffle 815 and an inlet filter 818, and exhaust the air through the air exhaust component 830 located in the rear door 804 or exhaust door of the outdoor enclosure system, wherein the air exhaust component or exhaust door assembly 830 comprises an exhaust fan blower assembly 834. Each of the blowers in the air intake component comprises a “check valve” type of flap system 836, such that if one of the plurality of blowers fails, the flaps on the failing blower will automatically close and prevent air from the other blowers recirculating back through the failed blower fan. Also, in this embodiment, each blower and related plurality of flaps is in a self-contained replaceable module to allow easy replacement, if needed. FIG. 8B shows the airflow 850 into the air intake component 810 and out of the air exhaust component 830 in this contemplated embodiment. FIG. 8C shows the intake door 870 and the exhaust door 880 from another view point.

Table 1 shows specifications for one contemplated embodiment that comprises a remote enclosure system; however, it should be appreciated that the remote enclosure system may be built or pre-configured to additional and/or different specifications. For example, under “Environmental” Table 1 shows that there is an air conditioner with a heater in the remote enclosure system. A humidifier or dehumidifier may also be added to the system, or an air conditioner without the heater and vice versa may be present or added in the system. Another example would be that the remote enclosure system can be designed to be smaller or larger depending on the needs of the remote site or remote lease site.

If the enclosure system is designed to accommodate at least one expansion cabinet then a contemplated internal environmental control system is designed to accommodate the environmental needs of the at least one additional cabinet. The at least one expansion cabinet can contain telecommunications components or electronic components that are subject to a demarcation shield from the original remote enclosure system. The at least one expansion cabinet is coupled to at least one of the frame system and/or at least one of the side panels at a coupling interface, which has been previously described. An insulating material may also be located at the coupling interface to insulate the internal space from the outside environment by closing any gaps between the at least one expansion cabinet and the frame system and/or the at least one side panel.

Contemplated electronic components comprise circuit boards, chip packaging, dielectric components of circuit boards, printed-wiring boards, and other components of circuit boards, such as capacitors, inductors, and resistors. As used herein, the phrase “remote site” is used herein to describe any site that is not the original assembly site for the remote enclosure system, and in many instances, refers to the site where the remote enclosure system is located before activation.

As used herein, the term “electronic component” also means any device or part that can be used in a circuit to obtain some desired electrical action. Electronic components contemplated herein may be classified in many different ways, including classification into active components and passive components. Active components are electronic components capable of some dynamic function, such as amplification, oscillation, or signal control, which usually requires a power source for its operation. Examples are bipolar transistors, field-effect transistors, and integrated circuits. Passive components are electronic components that are static in operation, i.e., are ordinarily incapable of amplification or oscillation, and usually require no power for their characteristic operation. Examples are conventional resistors, capacitors, inductors, diodes, rectifiers and fuses.

Electronic components contemplated herein may also be classified as conductors, semiconductors, or insulators. Here, conductors are components that allow charge carriers (such as electrons) to move with ease among atoms as in an electric current. Examples of conductor components are circuit traces and vias comprising metals. Insulators are components where the function is substantially related to the ability of a material to be extremely resistant to conduction of current, such as a material employed to electrically separate other components, while semiconductors are components having a function that is substantially related to the ability of a material to conduct current with a natural resistivity between conductors and insulators. Examples of semiconductor components are transistors, diodes, some lasers, rectifiers, thyristors and photosensors.

Electronic components contemplated herein may also be classified as power sources or power consumers. Power source components are typically used to power other components, and include batteries, capacitors, coils, and fuel cells. Power consuming components include resistors, transistors, integrated circuits (ICs), sensors, and the like.

Still further, electronic components contemplated herein may also be classified as discreet or integrated. Discreet components are devices that offer one particular electrical property concentrated at one place in a circuit. Examples are resistors, capacitors, diodes, and transistors. Integrated components are combinations of components that that can provide multiple electrical properties at one place in a circuit. Examples are integrated circuits in which multiple components and connecting traces are combined to perform multiple or complex functions such as logic.

Telecommunications components include fiber optic cable and other optical materials, such as waveguides, data transmission wires and lines, copper wire, coax cable, keyboards and monitors and the like.

Electronic components, telecommunications components and other suitable components can be attached to or placed on a shelf or shelving system located in the internal space of the remote enclosure system, wherein the shelf or shelving system is coupled to at least one of the frame system, the side panels, the cable management top assembly and/or the bottom panel. As mentioned earlier, electronic components, telecommunications components and other suitable components may also be directly coupled to one or more of the frame system, side panels, cable management top assembly and bottom panel without the assistance of a shelf or shelving system. It is also contemplated that certain components, such as a meter base or air conditioning unit may be primarily located outside of the remote enclosure system.

Several embodiments of the enclosure system and internal environmental control system are formulated out of non-corrosive aluminum, however, any suitable metal, composite material, polymer or plastic material, fiberglass or appropriate or suitable material or combination of materials may be used, as long as the material or materials is/are capable of successfully and efficiently housing power and telecommunications components. The material(s) that is/(are) exposed to the outdoor environment must also be able to withstand environmental conditions, such as heat, rain, snow, hail, ice, cold weather, high wind, pressure changes and/or dust storms. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, zinc, vanadium, aluminum, chromium, platinum, gold, silver, tungsten, molybdenum, cerium, promethium, and thorium. More preferred metals include titanium, silicon, copper, nickel, platinum, gold, silver and tungsten. Most preferred metals include titanium, silicon, copper and nickel. The term “metal” also includes alloys, metal/metal composites, metal ceramic composites, metal polymer composites, as well as other metal composites.

As an example, a remote enclosure system is contemplated herein and offers at least one of the following benefits/advantages (which are not necessarily intended to be objects of the invention):
a. All site electrical terminations are accomplished in one system or unit without the need for additional systems or units, hence reducing the site electrical costs by approximately $6K-$10K per site.
b. Overall lease site dimensions are reduced significantly because all or most of the terminations are consolidated.
c. Pre-termination of AC and DC equipment loads reduces site installation time by 4-6 hours.
d. Network construction timelines are improved by facilitating site electrical/telecommunications inspections before and outside of the arrival of the radio base stations.
e. The remote enclosure system provides multiple equipment access points for facilitating equipment repair and installation.
f. The remote enclosure system modular cabinet design allows for site expansion through the attachment of additional systems or cabinets.
g. Cable entry/routing allows for improved site aesthetics, which helps the site approval process through the local government.
h. Reliable and efficient internal environmental control.

Keeping with this theme, a contemplated remote enclosure system, including an internal environmental control system, can comprise a frame system where side, top and/or bottom panels and expansion cabinets are bolted in place to allow base modules that can be manufactured in high quantity optimized production runs. These contemplated remote enclosure systems can then provide rapid installation, set up, integration and utilization solutions for the customer, because instead of having to initially produce the entire cabinet, the enclosure system can be modified and plates produced that would bolt to the frame. Or two or more expansion cabinets can be bolted together and/or with the original frame system for greater space. Another advantage with this modular design is that assemblies can be outsourced to many fabricators depending on quantity and time requirements. Another benefit/advantage is, by virtue of the design, cabinetized solutions can be produced that are custom built, quickly and economically and provide an inherent growth platform for customers and end users.

A contemplated remote enclosure system may be produced by: a) providing a frame system having at least two side panels, at least one door coupled to the frame system, at least one removable RF port plate coupled to at least one of the side panels, a bottom panel coupled to the frame system, or a top assembly coupled to the frame system; b) providing an expansion cabinet; c) coupling the frame system to the expansion cabinet through a coupling interface; and d) coupling an internal environment control system to the frame system. Providing the frame system, the internal environment control system or the expansion cabinet may comprise obtaining these components from an outsourced vendor or producing all or some of the components in house. In addition, coupling the frame system to the expansion cabinet through a coupling interface may comprise any suitable coupling apparatus or device, as mentioned previously.

In some cases, the remote enclosure systems contemplated herein will comprise two or more of the benefits and advantages listed above, but it should be appreciated that remote enclosure systems contemplated herein may only comprise one of the benefits/advantages shown above, and that in no way limits the inherent usefulness of the remote enclosure system.

Thus, specific embodiments and applications of compositions and methods to construct and produce enclosure systems, including remote enclosure systems, comprising internal environmental control systems have been disclosed. It should be apparent, however, to those skilled in the art that many more modifications besides those already described are possible without departing from the inventive concepts herein. The inventive subject matter, therefore, is not to be restricted except in the spirit of the disclosure presented herein. Moreover, in interpreting the disclosure presented herein, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

I claim:

1. An internal environment control system for an outdoor enclosure system, comprising:
at least one air intake component coupled to the outdoor enclosure system,
at least one air exhaust component coupled to the outdoor enclosure system,
an environmental detection device,
an environmental regulation device coupled to the environmental detection device, the at least one air intake component, the at least one air exhaust component or a combination thereof, wherein the regulation device activates at least one of the at least one air intake component or the at least one air exhaust component, and
at least one porous membrane, hydrophobic filter or combination thereof coupled to the at least one air intake component.

2. The internal environment control system of claim 1, wherein the outdoor enclosure system comprises a remote enclosure system.

3. The internal environment control system of claim 2, wherein the remote enclosure system comprises at least one cabinet.

4. The internal environment control system of claim 3, wherein the remote enclosure system comprises at least two cabinets coupled to one another.

5. The internal environment control system of claim 1, wherein the at least one air intake component comprises at least one venting component.

6. The internal environment control system of claim 5, wherein the at least one venting component comprises a plurality of flaps.

7. The internal environment control system of claim 5, wherein the at least one venting component comprises a labyrinth filtered inlet.

8. The internal environment control system of claim 5, wherein the at least one venting component comprises at least one blower.

9. The internal environment control system of claim 5, wherein the at least one air intake component further comprises at least one temperature regulation component.

10. The internal environment control system of claim 9, wherein the at least one temperature regulation component comprises a heating element, a cooling element or a combination thereof.

11. The internal environment control system of claim 1, wherein the at least one exhaust component comprises at least one venting component.

12. The internal environment control system of claim 11, wherein the at least one venting component comprises a plurality of flaps.

13. The internal environment control system of claim 11, wherein the at least one venting component comprises at least one blower.

14. The internal environment control system of claim 1, wherein the environmental detection device senses a loss of AC power in the outdoor enclosure system.

15. The internal environment control system of claim 1, wherein the environmental detection device senses a change of pressure in the outdoor enclosure system.

16. The internal environment control system of claim 1, wherein the environmental detection device senses a change of temperature in the outdoor enclosure system.

17. The internal environment control system of claim 1, wherein the environmental regulation device activates at least one of the blowers in the at least one air intake component or the at least one air exhaust component, opens at least some of the plurality of flaps in the at least one air intake component or the at least one air exhaust component, creates a pressure differential in the internal environment or a combination thereof.

18. The internal environment control system of claim 1, wherein the environmental regulation device operates using DC power.

19. The internal environment control system of claim 1, wherein the at least one air intake component comprises at least one motor coupled to the venting component.

20. The internal environment control system of claim 1, wherein the at least one air exhaust component comprises at least one motor coupled to the venting component.

21. The internal environment control system of claim 1, wherein the environmental regulation device activates the at least one motor coupled to the venting component of the at least one air intake component, the at least one motor coupled to the venting component of the at least one air exhaust component or a combination thereof.

22. The internal environment control system of claim 1, wherein the at least one porous membrane, hydrophobic filter or combination thereof comprises GORE-TEX®, nylon, polyester or a combination thereof.

23. A method of controlling the internal environment of a remote enclosure system, comprising:
providing an internal environment control system that comprises at least one porous membrane, hydrophobic filter or combination thereof;
providing ambient air; and
directing the ambient air through the internal environment control system.

24. The method of claim 23, wherein the internal environment control system comprises an air intake component, an air exhaust component, an environmental detection device and an environmental regulation device coupled to the environmental detection device, the at least one air intake component, the at least one air exhaust component or a combination thereof, wherein the regulation device activates at least one of the at least one air intake component or the at least one air exhaust component.
